(19) United States
(12) Patent Application Publication
(10) Pub. No.: US 2025/0353106 A1
(43) Pub. Date: Nov. 20, 2025

(54) LASER LIFT-OFF APPARATUS AND SUBSTRATE LIFT-OFF METHOD USING THE SAME

(71) Applicant: Samsung Display Co., LTD., Yongin-si, (KR)

(72) Inventors: Cheol Ho PARK, Yongin-si (KR); Akifumi SANGU, Yongin-si (KR); Young Su CHAE, Yongin-si (KR)

(21) Appl. No.: 19/015,410

(22) Filed: Jan. 9, 2025

(30) Foreign Application Priority Data
May 20, 2024 (KR) 10-2024-0065038

(51) Int. Cl. B23K 26/06; B23K 101/36

(52) U.S. Cl. CPC B23K 26/0626; B23K 26/0648; B23K 2101/36

(57) ABSTRACT

Provided is a laser lift-off apparatus, and a substrate lift-off method using a laser lift-off apparatus. The laser lift-off apparatus is configured to convert a first beam into a second beam having a width in a first direction and in a second direction different from the first direction, the laser lift-off apparatus including a laser beam generator configured to generate the first beam, a homogenizer configured to homogenize the first beam, and a beam cutter including a first beam cutter and a second beam cutter defining at least two openings having different respective lengths in the first direction, and configured to generate the second beam by transmitting and blocking respective portions of the first beam.

The present application claims priority to and the benefit of Korean Patent Application No. 10-2024-0065038, filed on May 20, 2024, in the Korean Intellectual Property Office, the entire disclosure of which is incorporated herein by reference.

### BACKGROUND

### 1. Field

Embodiments of the present disclosure described herein are related to a laser lift-off apparatus and a substrate lift-off method using the laser lift-off apparatus.

### 2. Description of the Related Art

A display device can be manufactured as a flexible device using a highly flexible substrate.

However, because the flexible substrate has great flexibility, it may be suitable for the flexible substrate to be supported during a process of manufacturing the display device. Therefore, after the flexible substrate is formed on a carrier substrate made of a material such as glass, a process of manufacturing a flat panel display device is performed, and then the carrier substrate is removed.

The carrier substrate can be removed by one or more suitable methods. Among the methods, a laser lift-off method using a laser may be considered.

The above information disclosed in this Background section is only for enhancement of understanding of the background of the disclosure and therefore it may contain information that does not constitute prior art.

### SUMMARY

Aspects according to one or more embodiments of the present disclosure are directed toward a laser lift-off apparatus with improved reliability of a laser lift-off process and a substrate lift-off method using the laser lift-off apparatus.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, a laser lift-off apparatus is configured to convert a first beam into a second beam having a width in a first direction and in a second direction different from the first direction, the laser lift-off apparatus including a laser beam generator configured to generate the first beam, a homogenizer configured to homogenize the first beam, and a beam cutter including a first beam cutter and a second beam cutter defining at least two openings having different respective lengths in the first direction, and configured to generate the second beam by transmitting and blocking respective portions of the first beam.

The first beam cutter may define a first opening, and a second opening extending from the first opening in the second direction, wherein the second beam cutter defines a third opening, and a fourth opening extending from the third opening in the second direction.

A width of the first opening in the first direction may be greater than a width of the second opening in the first direction, wherein a width of the third opening in the first direction is greater than a width of the fourth opening in the first direction.

The first beam cutter may include a first end, wherein the second beam cutter includes a second end facing the first end, wherein the second opening bifurcates the first end, and wherein the third opening bifurcates the second end.

An energy profile of the second beam may include a first area, and a second area having higher energy than the first area.

The first area may correspond to the first beam passing through the second opening and the fourth opening.

The second area may include a first sub-area, and a second sub-area opposite to the first sub-area with the first area therebetween, wherein the first sub-area corresponds to the first beam passing through the first opening, and wherein the second sub-area corresponds to the first beam passing through the third opening.

The second area may include a margin area on a side of the first area, a slope area on a side of the margin area, and a high energy area on a side of the slope area.

A width of the margin area may be about 4 mm or more, wherein a width of the slope area is about 12 mm or less.

A shape of the first beam cutter and a shape of the second beam cutter may be symmetrical with respect to an axis extending in the first direction.

The first beam cutter and the second beam cutter may be arranged alternately in a third direction that is different from the first direction and the second direction.

The first beam cutter and the second beam cutter may further include a driver configured to provide a driving force in at least one of the first direction or the second direction.

The laser lift-off apparatus may further include a telescope lens between the laser beam generator and the homogenizer, and configured to magnify the first beam, or configured to transmit the first beam at a same magnification.

The laser lift-off apparatus may further include a short-axis slit between the homogenizer and the beam cutter, and defining an opening having a short width in the first direction and a long width in the second direction.

The laser lift-off apparatus may further include a short-axis Fourier lens between the homogenizer and the short-axis slit, and configured to focus the first beam transmitted through the telescope lens onto the short-axis slit along the first direction.

The laser lift-off apparatus may further include a long-axis Fourier lens between the short-axis slit and the beam cutter, and configured to focus the first beam transmitted through the telescope lens onto an image plane to which the second beam is incident.

The laser lift-off apparatus may further include a projection lens between the short-axis slit and the beam cutter, and configured to adjust a width of the first beam passing through the short-axis slit in at least any one of the first direction or the second direction.

According to one or more embodiments, a laser lift-off apparatus is configured to convert a first beam into a second beam having a width in a first direction and in a second direction that is different from the first direction, the laser lift-off apparatus including a laser beam generator configured to generate the first beam, a homogenizer configured to homogenize the first beam, and a beam cutter including a first beam cutter defining a first opening extending in the second direction and a second beam cutter defining a second opening extending in the second direction, and configured to generate the second beam by transmitting and blocking respective portions of the first beam.

An energy profile of the second beam may include a first area corresponding to the first beam passing through a space between the first beam cutter and the second beam cutter in the second direction, and a second area having higher energy than the first area.

The second area may include a first sub-area corresponding to the first beam passing through the first opening and the first beam passing through the space, and a second sub-area opposite to the first sub-area with the first area therebetween, and corresponding to the first beam passing through the second opening and the first beam passing through the space.

According to one or more embodiments of the present disclosure, a substrate lift-off method is for lifting off a carrier substrate from a first substrate of a display device including the carrier substrate, the first substrate above the carrier substrate, a barrier layer above the first substrate and that is larger than the first substrate in a plan view, and a second substrate above the barrier layer, the display device having a first area in which pixels are arranged, and a second area outside the first area and in which the barrier layer does not overlap the first substrate, the substrate lift-off method including irradiating a second beam, which is generated from a laser lift-off apparatus including a laser beam generator configured to generate a first beam, a homogenizer configured to homogenize the first beam, and a first beam cutter and a second beam cutter for generating the second beam by transmitting and blocking respective portions of the first beam, to the first area and to the second area by separating the first beam cutter and the second beam cutter, and irradiating the second beam to the second area by moving the first beam cutter and the second beam cutter closer to each other, an energy intensity of the second beam irradiated to the first area being less than an energy intensity of the second beam irradiated to the second area.

The first beam cutter may define a first opening, and the second beam cutter may define a second opening, the method further including passing the first beam through a space between the first beam cutter and the second beam cutter when irradiating the second beam to the first area and the second area by separating the first beam cutter and the second beam cutter, and passing the first beam through a space between the first opening and the second opening when irradiating the second beam to the second area by moving the first beam cutter and the second beam cutter closer to each other.

The display device may further have a third area between the first area and the second area, wherein an energy intensity of the second beam irradiated to the third area is greater than or equal to the energy intensity of the second beam irradiated to the first area, and less than or equal to the energy intensity of the second beam irradiated to the second area.

According to a laser lift-off apparatus and a substrate lift-off method using the laser lift-off apparatus according to one or more embodiments of the present disclosure, the reliability of a laser lift-off process can be improved.

However, the aspects of the present disclosure are not restricted to the one set forth herein. The above and other aspects of the present disclosure will become more apparent to one of daily skill in the art to which the present disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view of a display device being manufactured according to one or more embodiments;

FIG. 2 is a plan view of a carrier substrate and a panel substrate;

FIG. 3 is a cross-sectional view of the carrier substrate and the panel substrate;

FIG. 4 is a schematic diagram illustrating an energy profile of a final laser beam applied to the carrier substrate and the panel substrate during a laser lift-off process using a laser lift-off apparatus according to one or more embodiments;

FIG. 5 is a schematic block diagram of the laser lift-off apparatus according to one or more embodiments;

FIG. 6 is a schematic perspective view of the laser lift-off apparatus according to one or more embodiments;

FIG. 7 is a plan view of a beam cutter according to one or more embodiments;

FIGS. 8 and 9 are cross-sectional views of the beam cutter according to one or more embodiments;

FIG. 10 is an enlarged view of an XA area of FIG. 6;

FIG. 11 is an enlarged view of an XB area of FIG. 6;

FIG. 12 is an enlarged view of an XD area of FIG. 11;

FIG. 13 is an enlarged view of an XC area of FIG. 6;

FIG. 14 is a schematic cross-sectional view illustrating a process of lifting off the carrier substrate from the panel substrate using the laser lift-off apparatus according to one or more embodiments;

FIG. 15 is a plan view illustrating a process in which the beam cutter according to one or more embodiments adjusts the energy profile of the final laser beam by moving in a long-axis direction;

FIG. 16 and FIG. 17 are cross-sectional views illustrating the process in which the beam cutter according to one or more embodiments adjusts the energy profile of the final laser beam by moving in the long-axis direction;

FIG. 18 is a schematic diagram illustrating the energy profile of the final laser beam of the laser lift-off apparatus according to one or more embodiments;

FIG. 19 is a plan view illustrating a process in which the beam cutter according to one or more embodiments adjusts the energy profile of the final laser beam by moving in a short-axis direction;

FIG. 20 is a plan view illustrating a process in which the beam cutter according to one or more embodiments adjusts the energy profile of the final laser beam by moving in the long-axis direction and the short-axis direction;

FIG. 21 is a plan view of a beam cutter according to a first comparative embodiment;

FIG. 22 is a cross-sectional view of the beam cutter according to the first comparative embodiment;

FIG. 23 is a schematic diagram illustrating an energy profile of a final laser beam of a laser lift-off apparatus according to a first comparative embodiment;

FIG. 24 is an enlarged view of a portion corresponding to an XE area of FIG. 18 in the energy profile of the final laser beam of the laser lift-off apparatus according to one or more embodiments;

FIG. 25 is an enlarged view of a portion corresponding to the XE area of FIG. 18 in an energy profile of a final laser beam of a laser lift-off apparatus according to a second comparative embodiment;

FIG. 26 is a plan view illustrating a first laser irradiation operation using a beam cutter according to one or more embodiments;

FIG. 27 is a cross-sectional view illustrating the first laser irradiation operation using the beam cutter of FIG. 26;

FIG. 28 is a plan view illustrating a second laser irradiation operation using the beam cutter of FIG. 26; and

FIG. 29 is a cross-sectional view illustrating the second laser irradiation operation using the beam cutter of FIG. 26.

### DETAILED DESCRIPTION

The present disclosure will now be described in more detail hereinafter with reference to the accompanying drawings, in which example embodiments of the present disclosure are shown. This present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments of the present disclosure will be described in more detail with reference to the accompanying drawings.

Hereinafter, embodiments will be described in more detail with reference to the accompanying drawings.

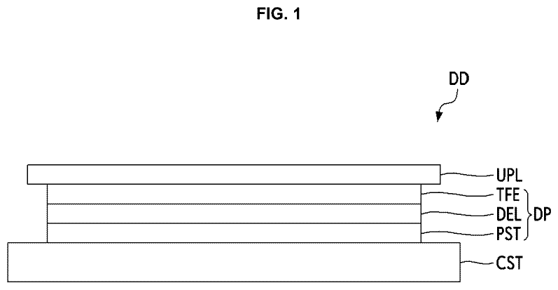

FIG. 1 is a cross-sectional view of a display device DD being manufactured according to one or more embodiments.

Referring to FIG. 1, the display device DD being manufactured according to one or more embodiments may include a carrier substrate CST, a display panel DP, and an upper protective layer UPL.

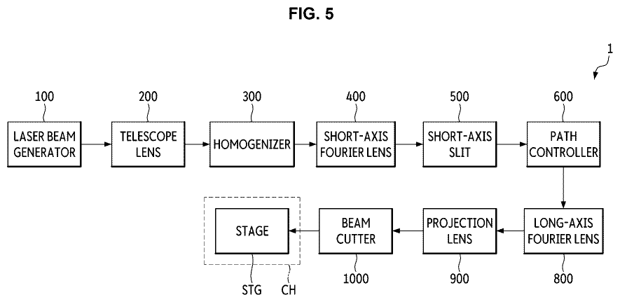

The carrier substrate CST may include a rigid material to serve as a support for supporting the display panel DP during a process of manufacturing the display device DD. The carrier substrate CST may be provided on a stage STG (see FIG. 5) during the process of manufacturing the display device DD.

The carrier substrate CST may include a transparent material to transmit a laser beam during a lift-off process using a laser. For example, the carrier substrate CST may be made of glass having SiO₂ as its main component. For another example, the carrier substrate CST may include at least one or more of borosilicate glass, fused silica glass, or quartz glass.

When the display device DD is completed, the carrier substrate CST may be lifted off from a panel substrate PST and removed from the display device DD.

The display panel DP may include the panel substrate PST, a display element layer DEL, and an encapsulation layer TFE.

The panel substrate PST may be on the carrier substrate CST. In one or more embodiments, the panel substrate PST may be, but is not limited to, a flexible substrate.

In one or more embodiments, the panel substrate PST may include a plastic material. For example, the panel substrate PST may be made of polyamide or polyimide having excellent heat resistance to withstand a high temperature process such as a low temperature polysilicon (LTPS) manufacturing process and having flexibility when processed into a film form. The panel substrate PST may be formed by spin-coating a polyamide or polyimide solution on the carrier substrate CST and then curing the solution or by attaching or laminating a film-type polyamide or polyimide substrate to the carrier substrate CST with an adhesive material.

The display element layer DEL may be on the panel substrate PST. The display element layer DEL may include a light-emitting element and a circuit element for driving the light-emitting element.

The encapsulation layer TFE may be on the display element layer DEL. The encapsulation layer TFE may seal the display element layer DEL. The encapsulation layer TFE may include (e.g., may be in the form of) a thin film or a multilayer. For example, the encapsulation layer TFE may be a thin-film encapsulation layer. The encapsulation layer TFE may have a structure in which a layer made of an inorganic material such as silicon oxide (SiOₓ) or silicon nitride (SiNₓ) and a layer made of an organic material such as epoxy or polyimide are alternately formed. However, the present disclosure is not limited thereto, and the encapsulation layer TFE may also include a layer made of low melting glass.

The upper protective layer UPL may be on the encapsulation layer TFE. The upper protective layer UPL may reduce or prevent the likelihood of damage to the encapsulation layer TFE while the panel substrate PST is lifted off from the carrier substrate CST. The upper protective layer UPL may be removed after the panel substrate PST is lifted off from the carrier substrate CST.

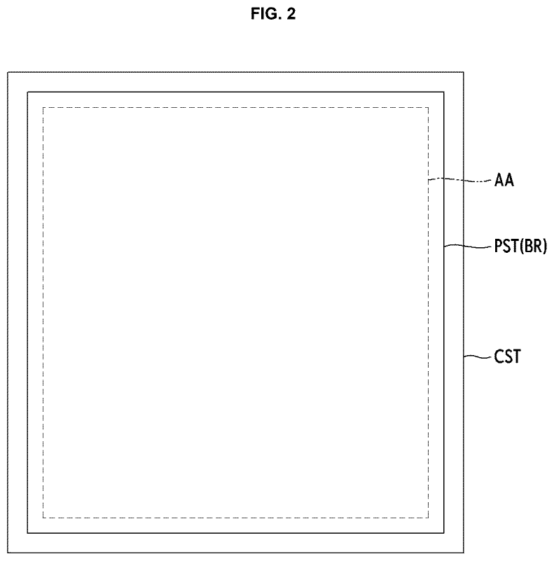

FIG. 2 is a plan view of the carrier substrate CST and the panel substrate PST.

Referring to FIG. 2 in addition to FIG. 1, the display device DD may include an active area AA. The active area AA may be an area in which a plurality of pixels are located. The active area AA may be an area which is configured to display an image. The active area AA may be referred to as a display area.

In one or more embodiments, a perimeter of the active area AA may be located inside a perimeter of the panel substrate PST. A size of the panel substrate PST may be larger than a size of the active area AA in plan view. An area of the panel substrate PST excluding the active area AA may be a non-active area or a non-display area. That is, an area of the panel substrate PST surrounding the active area AA (e.g., in plan view) may be a non-active area or a non-display area.

In one or more embodiments, the perimeter of the panel substrate PST may be located inside a perimeter of the carrier substrate CST. A size of the carrier substrate CST may be larger than the size of the panel substrate PST in plan view. That is, a length of a side of the carrier substrate CST may be greater than a corresponding side of the panel substrate PST.

The carrier substrate CST may include a boundary area BR. The boundary area BR may be a boundary of an area where the panel substrate PST and the carrier substrate CST overlapping each other begin to not overlap. For example, the panel substrate PST may be inside the boundary area BR and may not be outside the boundary area BR.

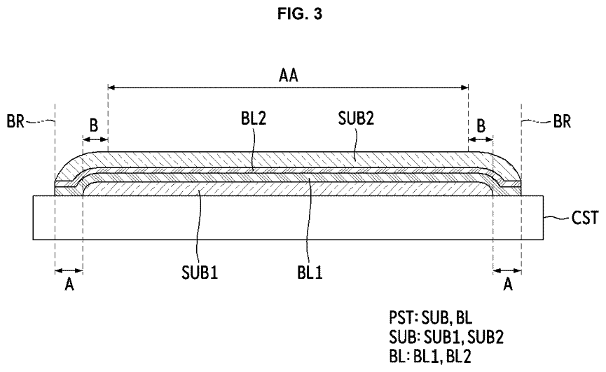

FIG. 3 is a cross-sectional view of the carrier substrate CST and the panel substrate PST.

Referring to FIG. 3 in addition to FIGS. 1 and 2, the panel substrate PST may include a substrate SUB and a barrier layer BL. The substrate SUB may include a first substrate SUB1 and a second substrate SUB2. The barrier layer BL may include a first barrier layer BL1 and a second barrier layer BL2.

Although the second substrate SUB2 is on the second barrier layer BL2 in the drawing, the present disclosure is not limited thereto. A stacking order of the second barrier layer BL2 and the second substrate SUB2 can be changed. For example, the second barrier layer BL2 may also be on the second substrate SUB2. A case where the second substrate SUB2 is on the second barrier layer BL2 will be described in more detail below as an example.

The first substrate SUB1 may be on the carrier substrate CST. The first substrate SUB1 may have a smaller area than the carrier substrate CST. Therefore, the first substrate SUB1 may not overlap at least a portion of the carrier substrate CST.

In one or more embodiments, the first substrate SUB1 may include an organic material. For example, the first substrate SUB1 may include one or more of polyamide resin or polyimide resin, but the present disclosure is not limited thereto.

The first barrier layer BL1 may be on the first substrate SUB1. The first barrier layer BL1 may have a larger area than the first substrate SUB1. Therefore, the first barrier layer BL1 may cover the entire first substrate SUB1. The first barrier layer BL1 may contact at least a portion of the carrier substrate CST.

In one or more embodiments, the first barrier layer BL1 may include an inorganic material. For example, the first barrier layer BL1 may include, but is not limited to, one or more of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), or silicon oxynitride (SiOₓN_{y}).

In one or more embodiments, the first barrier layer BL1 may include (e.g., be composed of) a single layer or multiple layers. For example, when the first barrier layer BL1 includes (e.g., is composed of) a single layer, the first barrier layer BL1 may be a single layer including one or more of the above-mentioned materials. For another example, when the first barrier layer BL1 includes (e.g., is composed of) multiple layers, the first barrier layer BL1 may include a first layer including one or more of the above-mentioned materials and a second layer on the first layer. Here, the second layer may include amorphous silicon (a-Si).

The second barrier layer BL2 may be on the first barrier layer BL1. The second barrier layer BL2 may have a larger area than the first barrier layer BL1. Therefore, the second barrier layer BL2 may cover the entire first barrier layer BL1.

In one or more embodiments, the second barrier layer BL2 may include an inorganic material. The second barrier layer BL2 may include one or more of the materials described above with reference to the first barrier layer BL1, but the present disclosure is not limited thereto.

The second substrate SUB2 may be on the second barrier layer BL2. The second substrate SUB2 may have a larger area than the first substrate SUB1. The second substrate SUB2 may have an end portion that does not overlap the first substrate SUB1. That is, a length of the second substrate SUB2 in a horizontal may be greater than a length of the first substrate SUB1 in the horizontal direction such that an end of the second substrate SUB2 does not overlap with the first substrate SUB1 in a plan view. When the second substrate SUB2 has a larger area than the first substrate SUB1, the second substrate SUB2 may include a protruding area A which protrudes further than the first substrate SUB1.

In one or more embodiments, the second substrate SUB2 may include an organic material. The second substrate SUB2 may include one or more of the materials described above with reference to the first substrate SUB1, but the present disclosure is not limited thereto.

The protruding area A may be located outside the active area AA. The protruding area A may surround the active area AA (e.g., in plan view). That is, the protruding portion area A does not overlap with the active area AA in a plan view. The protruding area A may overlap a portion of each of the first barrier layer BL1 and the second barrier layer BL2 located between the carrier substrate CST and the second substrate SUB2.

The boundary area BR may be located outside the protruding area A. That is, the boundary area BR does not overlap the protruding area A in a plan view. The boundary area BR may surround the protruding area A.

The second substrate SUB2 may further include a middle area B. The middle area B may be an area where the first substrate SUB1 directly contacts the carrier substrate CST, excluding (e.g., not including) the active area AA. In the middle area B, the first barrier layer BL1 and the second barrier layer BL2 may be located on the first substrate SUB1. The middle area B may be located between the active area AA and the protruding area A. The middle area B may be located outside the active area AA. That is, the middle area B does not overlap the active area AA in a plan view. The middle area B may surround the active area AA. The middle area B may be located inside the protruding area A and may be surrounded by the protruding area A.

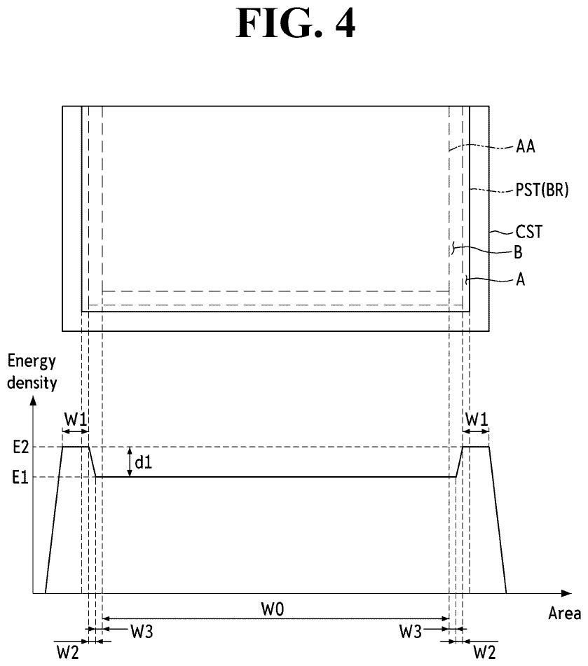

FIG. 4 is a schematic diagram illustrating an energy profile of a final laser beam applied to the carrier substrate CST and the panel substrate PST during a laser lift-off process using a laser lift-off apparatus according to one or more embodiments.

Referring to FIG. 4 in addition to FIGS. 1 through 3, in order to lift off the carrier substrate CST from the panel substrate PST, a laser lift-off apparatus 1 (see FIG. 5) may suitably apply appropriate energy to an area where the panel substrate PST and the carrier substrate CST contact each other. For example, if the laser lift-off apparatus 1 (see FIG. 5) fails to apply appropriate energy, the carrier substrate CST may not be properly lifted off from the first substrate SUB1, causing damage to elements of the display device DD.

Because pixels are located in the active area AA, the carrier substrate CST corresponding to the active area AA may be suitably lifted off with relatively lower energy than the carrier substrate CST corresponding to an area other than the active area AA in order to reduce or prevent damage to the pixels.

For example, if the laser lift-off apparatus 1 (see FIG. 5) applies high energy to the active area AA, the first substrate SUB1 may be damaged by the high energy of a laser beam. At this time, the adhesion of the elements on the first substrate SUB1 may be weakened, and the encapsulation layer TFE may be detached.

Therefore, the carrier substrate CST corresponding to the active area AA may be suitably lifted off using a laser beam having relatively low energy among laser beams incident on the panel substrate PST. The laser lift-off apparatus 1 (see FIG. 5) according to one or more embodiments to be described in more detail later may apply appropriately low energy to the active area AA. Therefore, the risk of the encapsulation layer TFE being detached can be reduced.

In one or more embodiments, because the protruding area A is an area where the first barrier layer BL1 and the second barrier layer BL2 are between the carrier substrate CST and the second substrate SUB2, an energy density of a laser beam reaching the second substrate SUB2 may be reduced by the first barrier layer BL1 and the second barrier layer BL2.

Therefore, the carrier substrate CST corresponding to the protruding area A may be suitably lifted off with relatively higher energy than the carrier substrate CST corresponding to the active area AA. If high energy is not applied to the protruding area A, the carrier substrate CST corresponding to the protruding area A of the second substrate SUB2 may not be lifted off. At this time, if a lift-off blade is used for complete lift-off, the first substrate SUB1 may be damaged when the lift-off blade is passed between the carrier substrate CST and the first substrate SUB1.

The laser lift-off apparatus 1 according to one or more embodiments to be described in more detail later can apply appropriately high energy to the protruding area A. Accordingly, the reliability of the laser lift-off process can be improved.

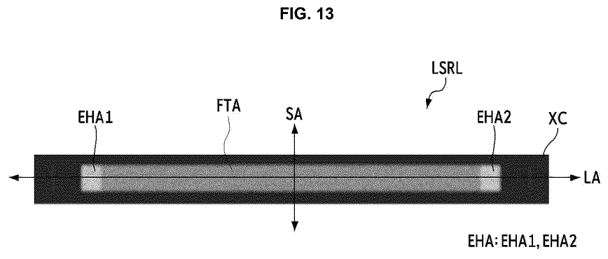

For example, as illustrated in FIG. 4, the carrier substrate CST corresponding to the active area AA may be lifted off by a laser beam having a first energy E1. In the active area AA, the laser beam may have a substantially uniform (e.g., generally uniform) first energy E1. The laser beam may have a low energy area W0, which is a constant section with the first energy E1, in an energy density graph by area. The low energy area W0 may be a flat top area FTA (see FIG. 13) to be described in more detail later.

The carrier substrate CST corresponding to the protruding area A and the boundary area BR may be lifted off by a laser beam having a second energy E2. In the protruding area A, the laser beam may have a substantially uniform (e.g., generally uniform) second energy E2. The laser beam may have a first area W1, which is a constant section with the second energy E2, in the energy density graph by area. The first area W1 may be an energy enhancement area EHA (see FIG. 13) to be described in more detail later. The first energy E1 may be lower than the second energy E2. The first energy E1 and the second energy E2 may have an energy difference (e.g., predetermined energy difference) d1.

The carrier substrate CST corresponding to the middle area B may be lifted off by a laser beam having the first energy E1 to the second energy E2. A portion of the laser beam may have a substantially uniform (e.g., generally uniform) first energy E1 in the middle area B, and the other portion of the laser beam may have the first energy E1 to the second energy E2. For example, in the energy density graph by area, the laser beam may have a second area W2 which is a section of the first energy E1 to the second energy E2 and a third area W3 which is a constant section of the first energy E1.

The second area W2 may be a slope area. The second area W2 may be an in-between section in which the energy changes from the low energy area W0 to the first area W1. A width of the second area W2 may vary according to the optical system configuration of the laser lift-off apparatus 1 (see FIG. 5) to be described in more detail later.

The third area W3 may be a safety margin area. The third area W3 may be a margin area for reducing or preventing the likelihood of a laser beam having higher energy than the first energy E1 being irradiated to the active area AA due to an error caused by an alignment error of the optical system configuration of the laser lift-off apparatus 1 (see FIG. 5).

The laser lift-off apparatus 1 (see FIG. 5) according to one or more embodiments to be described in more detail later may irradiate appropriate energy to each area as described above. For example, the laser lift-off apparatus 1 (see FIG. 5) may irradiate a beam of the low energy area W0 to protect the active area AA from a laser beam, may irradiate a beam of the first area W1 to intensify the lift-off of the carrier substrate CST corresponding to the protruding area A, may secure a minimum width of the third area W3 to protect the active area AA, and may reduce or minimize the width of the second area W2 where energy changes to accurately irradiate the beams of the low energy area W0 and the first area W1 to the active area AA and the protruding area A, respectively.

The laser lift-off apparatus 1 (see FIG. 5) and a method used by the laser lift-off apparatus 1 (see FIG. 5) to adjust the energy of a laser beam incident to each area will now be described in more detail with reference to FIG. 5, etc.

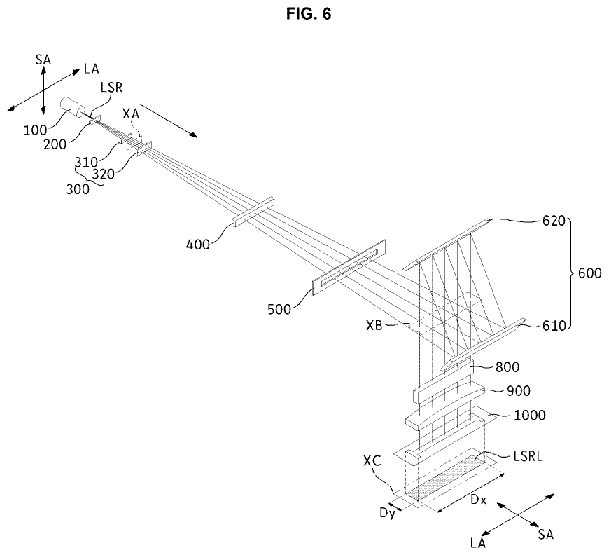

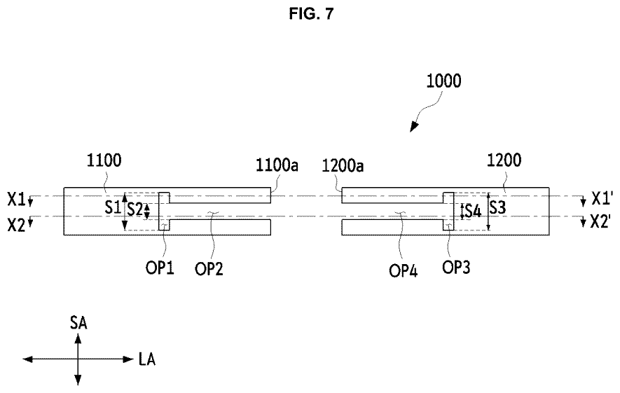

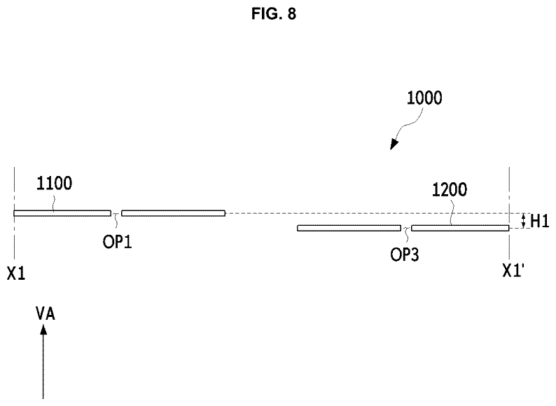

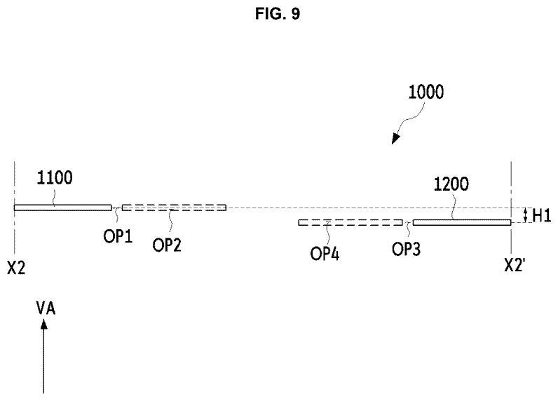

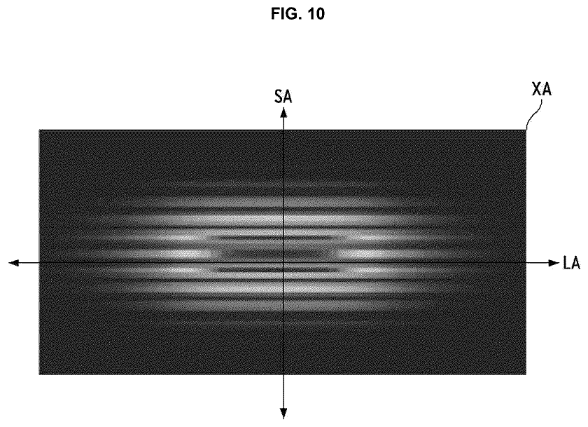

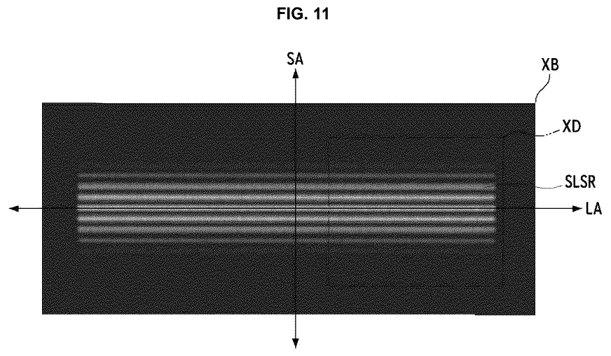

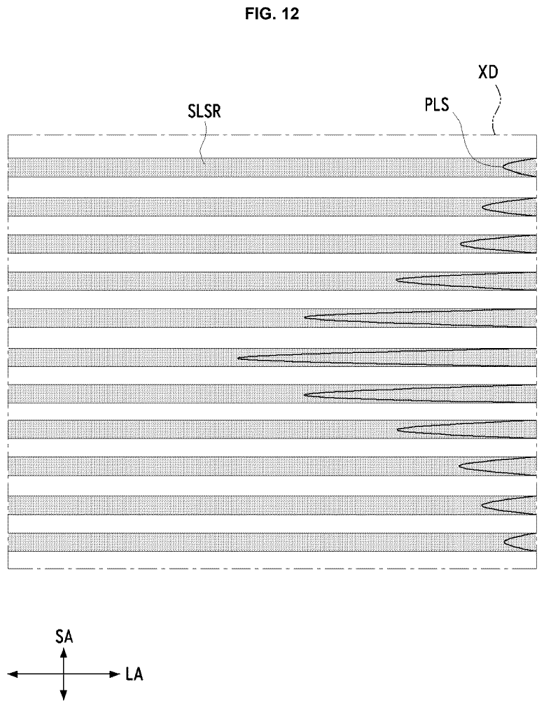

FIG. 5 is a schematic block diagram of a laser lift-off apparatus 1 according to one or more embodiments. FIG. 6 is a schematic perspective view of the laser lift-off apparatus 1 according to one or more embodiments. FIG. 7 is a plan view of a beam cutter 1000 according to one or more embodiments. FIGS. 8 and 9 are cross-sectional views of the beam cutter 1000 according to one or more embodiments. FIG. 10 is an enlarged view of an XA area of FIG. 6. FIG. 11 is an enlarged view of an XB area of FIG. 6. FIG. 12 is an enlarged view of an XD area of FIG. 11. FIG. 13 is an enlarged view of an XC area of FIG. 6.

Referring to FIGS. 5 through 13, the laser lift-off apparatus 1 according to one or more embodiments may be an apparatus for lifting off the carrier substrate CST from the panel substrate PST using a laser. For example, the laser lift-off apparatus 1 may be, but is not limited to, an excimer laser peeler (ELP).

The laser lift-off apparatus 1 may include a laser beam generator 100, a telescope lens 200, a homogenizer 300, a short-axis Fourier lens 400, a short-axis slit 500, a path controller 600, a long-axis Fourier lens 800, a projection lens 900, the beam cutter 1000, and a stage STG.

The laser beam generator 100 may be configured to generate a laser beam LSR. In one or more embodiments, the laser beam generator 100 may be configured to generate the laser beam LSR using an excimer laser. However, the present disclosure is not limited thereto. In one or more embodiments, the laser beam generator 100 may be configured to generate the laser beam LSR using a solid-state laser.

The laser beam generator 100 may include at least one light source. The light source may be configured to generate the laser beam LSR using a laser. The laser beam LSR may be generated in a Gaussian shape. The laser beam LSR may have a wavelength of about 300 to about 410 nm, but the present disclosure is not limited thereto.

The laser beam LSR may be converted into a final laser beam LSRL through a number of optical devices. The final laser beam LSRL may have a line shape having a long-axis length Dx in a long-axis direction LA and a short-axis length Dy in a short-axis direction SA.

The optical devices will now be described in more detail. The optical devices may include the telescope lens 200, the homogenizer 300, the short-axis Fourier lens 400, the short-axis slit 500, the path controller 600, the long-axis Fourier lens 800, the projection lens 900, and the beam cutter 1000.

In the drawings, one or more embodiments in which the telescope lens 200, the homogenizer 300, the short-axis Fourier lens 400, the short-axis slit 500, the long-axis Fourier lens 800, and the projection lens 900 are implemented as lenses is illustrated as an example. However, the present disclosure is not limited thereto. For example, the telescope lens 200, the homogenizer 300, the short-axis Fourier lens 400, the short-axis slit 500, the long-axis Fourier lens 800, and the projection lens 900 may also be implemented using at least one of a lens and a mirror.

The telescope lens 200 may be configured to magnify and may be configured to transmit the laser beam LSR incident on the telescope lens 200 or may be configured to transmit the laser beam LSR at the same magnification. In one or more embodiments, the telescope lens 200 may include a first telescope lens that is configured to adjust the degree of magnification (or magnification) in the long-axis direction LA and a second telescope lens that is configured to adjust the degree of magnification (or magnification) in the short-axis direction SA. However, the present disclosure is not limited thereto, and one telescope lens 200 may also be configured to adjust the degree of magnification (or magnification) in both the long-axis direction LA and the short-axis direction SA.

The homogenizer 300 may be configured to convert the laser beam LSR having an energy density of a Gaussian distribution into the laser beam LSR having a uniform energy density in the long-axis direction LA and the short-axis direction SA. The homogenizer 300 may include at least any one of a saw tooth lens, a light guide made of mirrors, or a fly's eye lens.

In one or more embodiments, the homogenizer 300 may include a short-axis homogenizer 310 and a long-axis homogenizer 320. The short-axis homogenizer 310 may be configured to generate the laser beam LSR having a uniform energy density in the short-axis direction SA, and the long-axis homogenizer 320 may be configured to generate the laser beam LSR having a uniform energy density in the long-axis direction LA.

For example, FIG. 10 shows the illuminance distribution of the laser beam LSR being passed through the short-axis homogenizer 310. As shown in FIG. 10, the laser beam LSR being passed through the short-axis homogenizer 310 may have a substantially uniform (e.g., uniform) energy density in the short-axis direction SA. For example, the laser beam LSR being passed through the short-axis homogenizer 310 may be divided into a plurality of laser beams LSR spaced apart at regular intervals along the short-axis direction SA. The laser beams LSR spaced apart at regular intervals along the short-axis direction SA may have a substantially uniform (e.g., uniform) energy density.

In one or more embodiments, the laser beam LSR being passed through the long-axis homogenizer 320 may have a substantially uniform (e.g., uniform) energy density in the long-axis direction LA. For example, the laser beam LSR being passed through the long-axis homogenizer 320 may be divided into a plurality of laser beams LSR spaced apart at regular intervals along the long-axis direction LA. The laser beams LSR spaced apart at regular intervals along the long-axis direction LA may have a substantially uniform (e.g., uniform) energy density.

In the drawings, the laser beam LSR may be passed through the short-axis homogenizer 310 and then the long-axis homogenizer 320. However, the present disclosure is not limited thereto. For example, the order of the short-axis homogenizer 310 and the long-axis homogenizer 320 may be reversed. In this case, the laser beam LSR may be passed through the long-axis homogenizer 320 and then the short-axis homogenizer 310.

The short-axis Fourier lens 400 may change the path of the laser beam LSR so that the laser beam LSR spread by the short-axis homogenizer 310 along the short-axis direction SA can be focused onto the short-axis slit 500. In one or more embodiments, the short-axis Fourier lens 400 may include, but is not limited to, a cylindrical convex lens.

The short-axis slit 500 may determine a width of the laser beam LSR in the short-axis direction SA. For example, the short-axis slit 500 may include an opening having a short width in the short-axis direction SA and a long width in the long-axis direction LA. The laser beam LSR being passed through the opening of the short-axis slit 500 may include a plurality of segment laser beams SLSR as shown in FIG. 11. A width of each of the segment laser beams SLSR in the short-axis direction SA may be limited by the width of the opening. For example, the width of each of the segment laser beams SLSR in the short-axis direction SA may be less than the width of the opening.

For example, FIG. 11 shows the illuminance distribution of the laser beam LSR being passed through the short-axis slit 500. FIG. 12 is an enlarged view of a part of FIG. 11. As shown in FIGS. 11 and 12, the laser beam LSR being passed through the short-axis slit 500 may include a plurality of segment laser beams SLSR spaced apart from each other in the short-axis direction SA. The laser beam LSR being passed through the short-axis slit 500 may be segmented into a plurality of segment laser beams SLSR by a diffraction phenomenon.

In one or more embodiments, intensities of the segment laser beams SLSR may increase from edges toward a center in the short-axis direction SA. For example, pulses PLS of the segment laser beams SLSR may increase from the edges toward the center. However, the present disclosure is not limited thereto, and the intensities of the segment laser beams SLSR may also be the same.

The path controller 600 may control the travel distance and direction of the laser beam LSR according to the design structure of the laser lift-off apparatus 1. In one or more embodiments, the path controller 600 may include at least one reflective mirror. For example, the path controller 600 may include a first mirror 610 and a second mirror 620. However, the present disclosure is not limited thereto. The number and positions of reflective mirrors can be variously changed.

The laser beam LSR may change its direction of travel by being reflected by a mirror. The distance traveled by the laser beam LSR may increase even within a narrow space according to the degree to which the direction of travel is changed. Accordingly, the focus and degree of spread of the laser beam LSR may change.

In one or more embodiments, the path controller 600 may not be provided.

The long-axis Fourier lens 800 may change the path of the laser beam LSR so that the laser beam LSR spread by the long-axis homogenizer 320 along the long-axis direction LA can be focused onto an image plane. In one or more embodiments, the long-axis Fourier lens 800 may include, but is not limited to, a cylindrical convex lens.

The projection lens 900 may be configured to adjust the width of the laser beam LSR in the short-axis direction SA and the width of the laser beam LSR in the long-axis direction LA. The projection lens 900 may be configured to adjust the width of the laser beam LSR in the short-axis direction SA and the long-axis direction LA while maintaining the shape of the laser beam LSR.

In the drawings, the laser beam LSR being passed through the long-axis Fourier lens 800 and then the projection lens 900. However, the present disclosure is not limited thereto. For example, the order of the long-axis Fourier lens 800 and the projection lens 900 may be reversed. In this case, the laser beam LSR may be configured to pass through the projection lens 900 and then the long-axis Fourier lens 800.

The beam cutter 1000 may be located between the projection lens 900 and the image plane (e.g., the stage STG). The beam cutter 1000 may block the path of a portion of the laser beam LSR incident on the beam cutter 1000 by reflecting or absorbing the portion of the laser beam LSR incident on the beam cutter 1000. The beam cutter 1000 may block a portion of the laser beam LSR incident on the beam cutter 1000 and be configured to transmit a portion of the laser beam LSR, thereby increasing or decreasing the energy density in a specific area of the final laser beam LSRL.

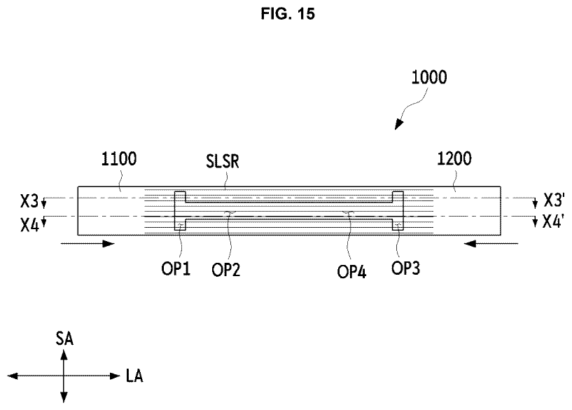

In one or more embodiments, as illustrated in FIG. 7, the beam cutter 1000 may include a first beam cutter 1100 and a second beam cutter 1200. The first beam cutter 1100 and the second beam cutter 1200 may be spaced apart from each other in the long-axis direction LA. However, the present disclosure is not limited thereto, and the first beam cutter 1100 and the second beam cutter 1200 may also overlap each other by moving in the long-axis direction LA as will be described in more detail later in FIG. 15, etc.

The first beam cutter 1100 may include a first opening OP1 and a second opening OP2, and the second beam cutter 1200 may include a third opening OP3 and a fourth opening OP4. The first opening OP1 and the second opening OP2 may be physically connected (or integrated) with each other, and the third opening OP3 and the fourth opening OP4 may be physically connected (or integrated) with each other.

In the long-axis direction LA, the second opening OP2 may be located on a side of the first opening OP1, for example, on a side adjacent to the second beam cutter 1200. That is, the second opening OP2 may be located between the first opening OP1 and the second beam cutter 1200 in the long-axis direction LA. In the long-axis direction LA, the fourth opening OP4 may be located on a side of the third opening OP3, for example, on a side adjacent to the first beam cutter 1100. That is, the fourth opening OP4 may be located between the third opening OP3 and the first beam cutter 1100 in the long-axis direction LA.

The first opening OP1 and the third opening OP3 may be extended in the short-axis direction SA, and the second opening OP2 and the fourth opening OP4 may be extended in the long-axis direction LA. The first opening OP1 may be approximately at a center of the first beam cutter 1100, and the third opening OP3 may be approximately at a center of the second beam cutter 1200. The second opening OP2 may be extended from the first opening OP1 in the long-axis direction LA to cut (or penetrate, divide, bifurcate) an end 1100a of the first beam cutter 1100 in the long-axis direction LA. The fourth opening OP4 may be extended from the third opening OP3 in the long-axis direction LA to cut (or penetrate, divide, bifurcate) an end 1200a of the second beam cutter 1200 in the long-axis direction LA.

In one or more embodiments, shapes of the first beam cutter 1100 and the second beam cutter 1200 may be symmetrical to each other with respect to an axis being extended in the short-axis direction SA, but the present disclosure is not limited thereto.

The first beam cutter 1100 and the second beam cutter 1200 may be arranged alternately in a vertical direction VA. For example, the first beam cutter 1100 may be higher than the second beam cutter 1200 by a first height difference H1. Accordingly, when the first beam cutter 1100 and the second beam cutter 1200 move in the long-axis direction LA to overlap each other in the vertical direction VA as will be described in more detail later in FIG. 15, etc., the likelihood of them interfering with each other may be reduced or prevented.

In the drawings, the vertical direction VA may be a direction intersecting, for example, and being orthogonal to the long-axis direction LA and the short-axis direction SA. The vertical direction VA may be a direction parallel to the path direction of the laser beam LSR.

A length S1 of the first opening OP1 in the short-axis direction SA may be greater than a length S2 of the second opening OP2 in the short-axis direction SA. A length S3 of the third opening OP3 in the short-axis direction SA may be greater than a length S4 of the fourth opening OP4 in the short-axis direction SA. Accordingly, the beam cutter 1000 can increase or decrease the energy density in a specific area of the final laser beam LSRL.

For example, FIG. 13 shows the illuminance distribution of the final laser beam LSRL. After the laser beam LSR is passed through the beam cutter 1000, the final laser beam LSRL may include a flat top area FTA and an energy enhancement area EHA in an energy profile. The energy enhancement area EHA may be a portion having a higher energy density than the flat top area FTA.

The flat top area FTA may be an area whose energy density is lowered by the laser beam LSR being passed through the second opening OP2 and the fourth opening OP4. The energy enhancement area EHA may include a first energy enhancement area EHA1 and a second energy enhancement area EHA2. The first energy enhancement area EHA1 may be an area whose energy density is increased by the laser beam LSR being passed through the first opening OP1, and the second energy enhancement area EHA2 may be an area whose energy density is increased by the laser beam LSR being passed through the third opening OP3.

A method of forming the flat top area FTA and the energy enhancement area EHA using the beam cutter 1000 will be described in more detail later with reference to FIGS. 15 through 20.

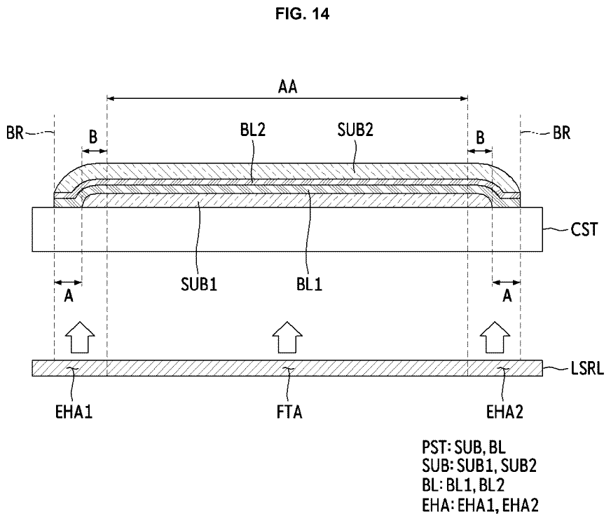

A laser lift-off process performed using the final laser beam LSRL including the flat top area FTA and the energy enhancement area EHA will now be described in more detail with reference to FIG. 14.

FIG. 14 is a schematic cross-sectional view illustrating a process of lifting off the carrier substrate CST from the panel substrate PST using the laser lift-off apparatus 1 according to one or more embodiments.

Referring to FIG. 14 in addition to FIGS. 4 through 13, the carrier substrate CST in the active area AA may be lifted off by the final laser beam LSRL having the energy density of the flat top area FTA. As described above, because pixels are in the active area AA, the carrier substrate CST corresponding to the active area AA may be lifted off by the final laser beam LSRL having the energy density of the flat top area FTA with relatively low energy. Accordingly, weakening of the adhesion of the elements on the first substrate SUB1 can be reduced or prevented, and damage to the elements can be minimized or reduced.

The carrier substrate CST corresponding to the protruding area A and the boundary area BR may be lifted off by the final laser beam LSRL having the energy density of the energy enhancement area EHA. As described above, because the barrier layer BL is between the carrier substrate CST and the second substrate SUB2 in the protruding area A, the carrier substrate CST corresponding to the protruding area A may be lifted off by the final laser beam LSRL having the energy density of the energy enhancement area EHA with relatively high energy. Accordingly, sufficient energy can be applied to the protruding area A, thereby completely lifting off the carrier substrate CST. Accordingly, because a lift-off blade is not used, damage to the first substrate SUB1 can be minimized or reduced. Therefore, the reliability of the laser lift-off process can be improved.

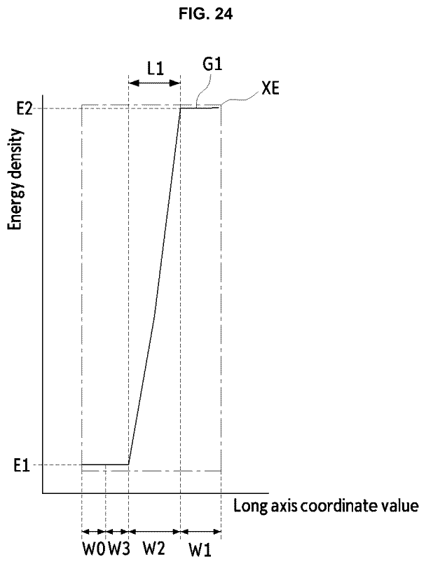

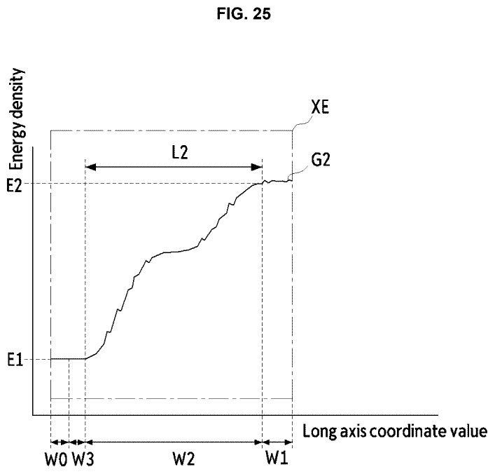

As described above with reference to FIG. 4, the laser beam LSR of the second area W2 and the third area W3 may be irradiated to the middle area B. The laser beam LSR of the second area W2 and the third area W3 may be included in the energy enhancement area EHA. The relationship between the second and third areas W2 and W3 and the energy enhancement area EHA will be described in more detail later with reference to FIGS. 24 and 25.

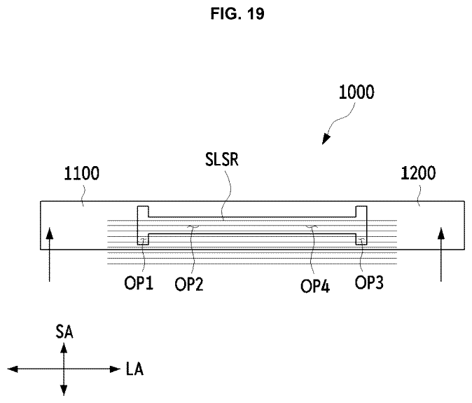

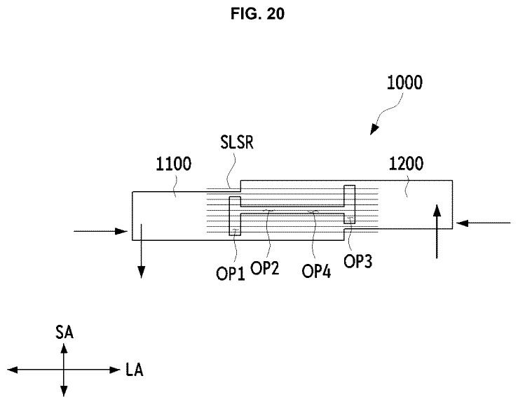

A method of forming the flat top area FTA and the energy enhancement area EHA of the final laser beam LSRL will now be described in more detail. A method of adjusting positions and widths of the flat top area FTA and the energy enhancement area EHA will be described in more detail with reference to FIGS. 15 through 18, and a method of adjusting sizes of energy densities of the flat top area FTA and the energy enhancement area EHA will be described in more details with reference to FIG. 19. A method of adjusting all of the positions, widths and energy densities of the flat top area FTA and the energy enhancement area EHA will be described in more detail with reference to FIG. 20.

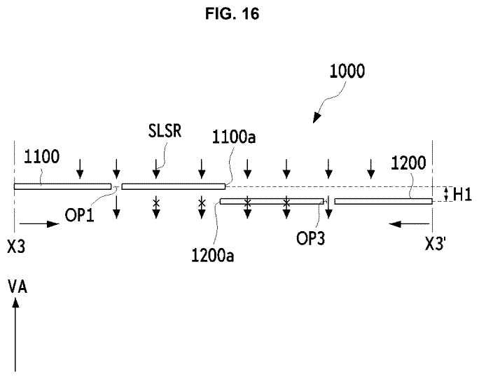

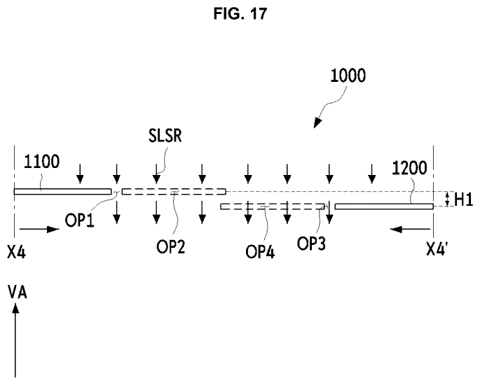

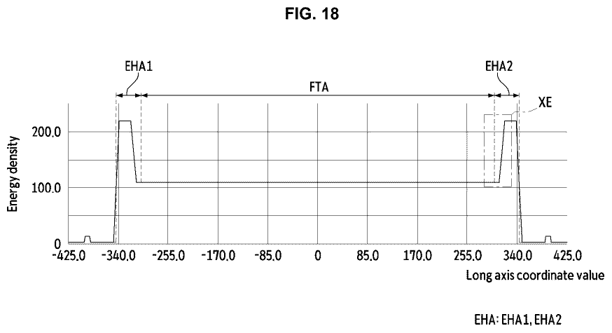

FIG. 15 is a plan view illustrating a process in which the beam cutter 1000 according to one or more embodiments is configured to adjust the energy profile of the final laser beam LSRL by moving in the long-axis direction LA. FIG. 16 and FIG. 17 are cross-sectional views illustrating the process in which the beam cutter 1000 according to one or more embodiments is configured to adjust the energy profile of the final laser beam LSRL by moving in the long-axis direction LA. FIG. 18 is a schematic diagram illustrating the energy profile of the final laser beam LSRL of the laser lift-off apparatus 1 according to one or more embodiments.

Referring to FIGS. 15 through 18, each of the first beam cutter 1100 and the second beam cutter 1200 may further include a separate driver that is configured to provide a driving force in the long-axis direction LA. Accordingly, each of the first beam cutter 1100 and the second beam cutter 1200 can move in the long-axis direction LA.

The first beam cutter 1100 and the second beam cutter 1200 illustrated in FIGS. 16 and 17 may at least partially overlap each other in the vertical direction VA, or the end 1100a of the first beam cutter 1100 and the end 1200a of the second beam cutter 1200 may coincide with each other in the vertical direction VA. Accordingly, as illustrated in FIG. 15, the second opening OP2 and the fourth opening OP4 may appear to be connected (or integrated) as one opening in a plan view. For example, an opening into which the first through fourth openings OP1 through OP4 of the beam cutter 1000 are combined in this state may have an H shape.

As illustrated in FIG. 16, in a cross section, in the long-axis direction LA, of a portion where the first opening OP1 and the third opening OP3 do not overlap the second opening OP2 and the fourth opening OP4 (e.g., a cross section taken along X3-X3′), a portion of each of the segment laser beams SLSR may be passed through the first opening OP1 and the third opening OP3, but the other portion may be blocked by the first beam cutter 1100 and the second beam cutter 1200 between the first opening OP1 and the third opening OP3.

As illustrated in FIG. 17, in a cross section, in the long-axis direction LA, of a portion where the second opening OP2 and the fourth opening OP4 are arranged (e.g., a cross section taken along X4-X4′), the segment laser beams SLSR may be passed through all of the first through fourth openings OP1 through OP4.

Therefore, the amount of segment laser beams SLSR being passed through an opening per unit area in the short-axis direction SA may be greater in an area where the first opening OP1 and the third opening OP3 are arranged than in an area where the second opening OP2 and the fourth opening OP4 are arranged.

Accordingly, as illustrated in FIG. 18, the final laser beam LSRL may include the flat top area FTA whose energy density is lowered by the laser beam LSR being passed through the second opening OP2 and the fourth opening OP4 and the energy enhancement area EHA whose energy density is increased by the laser beam LSR being passed through the first opening OP1 and the third opening OP3.

In one or more embodiments, when the first beam cutter 1100 and the second beam cutter 1200 move toward a center in the long-axis direction LA, the first energy enhancement area EHA1 and the second energy enhancement area EHA2 of the final laser beam LSRL may move toward the center, and the width of the flat top area FTA of the final laser beam LSRL may be reduced.

Because the sizes and positions of the active area AA, the protruding area A, the middle area B, and the boundary area BR are different in each display device DD (see FIG. 1) to be manufactured, the positions and widths of the flat top area FTA and the energy enhancement area EHA also may be suitably changed according to the display device DD to be manufactured.

The laser lift-off apparatus 1 can suitably adjust the positions and widths of the flat top area FTA and the energy enhancement area EHA by adjusting the position of the beam cutter 1000 in the long-axis direction LA. Therefore, without the need to replace the beam cutter 1000 for each display device DD to be manufactured, the positions and widths of the flat top area FTA and the energy enhancement area EHA can be adjusted by a method such as adjusting the position of the beam cutter 1000 in the long-axis direction LA by including a separate driver that is configured to provide a driving force in the long-axis direction LA.

FIG. 19 is a plan view illustrating a process in which the beam cutter 1000 adjusts the energy profile of the final laser beam LSRL by moving in the short-axis direction SA.

Referring to FIG. 19 in addition to FIGS. 15 through 18, each of the first beam cutter 1100 and the second beam cutter 1200 may further include a separate driver that is configured to provide a driving force in the short-axis direction SA. Accordingly, each of the first beam cutter 1100 and the second beam cutter 1200 can move in the short-axis direction SA.

As in FIG. 15, the first beam cutter 1100 and the second beam cutter 1200 illustrated in FIG. 19 may at least partially overlap each other in the vertical direction VA, or the end 1100a of the first beam cutter 1100 and the end 1200a of the second beam cutter 1200 may coincide with each other in the vertical direction VA. That is, the end 1100a of the first beam cutter 1100 and the end 1200a of the second beam cutter 1200 may overlap each other in the vertical direction VA. Accordingly, as in FIG. 15, an opening into which the first through fourth openings OP1 through OP4 of the beam cutter 1000 are combined may have an H shape.

When each of the first beam cutter 1100 and the second beam cutter 1200 moves toward an edge of the segment laser beams SLSR in the short-axis direction SA, the amount of segment laser beams SLSR being passed through an opening per unit area in the short-axis direction SA may be reduced compared with when each of the first beam cutter 1100 and the second beam cutter 1200 is located at a center of the segment laser beams SLSR in the short-axis direction SA as in FIG. 15.

Accordingly, the energy densities of the flat top area FTA and the energy enhancement area EHA (e.g., the first energy E1 and the second energy E2 of FIG. 4) may be lowered in the energy profile of the final laser beam LSRL illustrated in FIG. 18.

Because transmittances of the active area AA, the protruding area A, the middle area B, and the boundary area BR are different in each display device DD (see FIG. 1) to be manufactured, intensities of the energy densities of the flat top area FTA and the energy enhancement area EHA also may be suitably changed according to the display device DD to be manufactured.

The laser lift-off apparatus 1 can suitably adjust the intensities of the energy densities of the flat top area FTA and the energy enhancement area EHA by adjusting the amount of segment laser beams SLSR overlapping the openings of the beam cutter 1000 by adjusting the position of the beam cutter 1000 in the short-axis direction SA. Therefore, without the need to replace the beam cutter 1000 for each display device DD to be manufactured, the intensities of the energy densities of the flat top area FTA and the energy enhancement area EHA can be adjusted by a method such as adjusting the position of the beam cutter 1000 in the short-axis direction SA by including a separate driver that is configured to provide a driving force in the short-axis direction SA.

FIG. 20 is a plan view illustrating a process in which the beam cutter 1000 is configured to adjust the energy profile of the final laser beam LSRL by moving in the long-axis direction LA and the short-axis direction SA.

Referring to FIG. 20 in addition to FIGS. 15 through 19, each of the first beam cutter 1100 and the second beam cutter 1200 may move in the long-axis direction LA and the short-axis direction SA. For example, the first beam cutter 1100 and the second beam cutter 1200 may move toward the center in the long-axis direction LA. In the short-axis direction SA, the first beam cutter 1100 may move to one side, and the second beam cutter 1200 may move to the other side.

Accordingly, a width, in the short-axis direction SA, of an opening into which the second opening OP2 and the fourth opening OP4 are combined may be further reduced. In one or more embodiments, the amount of segment laser beams SLSR being passed through the first opening OP1 and the third opening OP3 per unit area may be greater than in the case of FIG. 19.

In this way, the laser lift-off apparatus 1 can adjust the positions, widths and intensities of energy densities of the flat top area FTA and the energy enhancement area EHA by adjusting the positions of the first beam cutter 1100 and the second beam cutter 1200 in the long-axis direction LA and the short-axis direction SA.

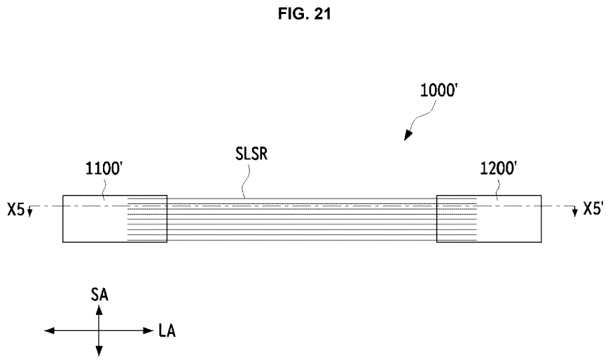

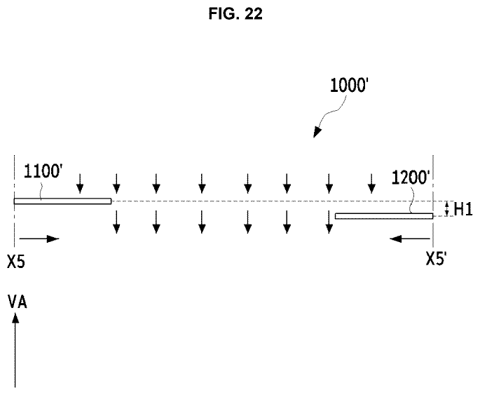

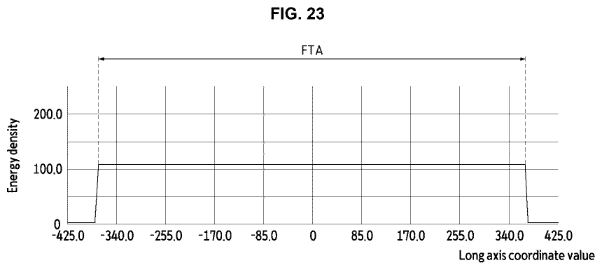

FIG. 21 is a plan view of a beam cutter 1000′ according to a first comparative embodiment. FIG. 22 is a cross-sectional view of the beam cutter 1000′ according to the first comparative embodiment. FIG. 23 is a schematic diagram illustrating an energy profile of a final laser beam LSRL of a laser lift-off apparatus according to a first comparative embodiment.

Referring to FIGS. 21 through 23 in addition to FIG. 18, the beam cutter 1000′ according to the first comparative embodiment may include a first beam cutter 1100′ and a second beam cutter 1200′. The first beam cutter 1100′ and the second beam cutter 1200′ of the beam cutter 1000′ according to the first comparative embodiment may not include an opening.

The beam cutter 1000′ according to the first comparative embodiment may transmit a portion of each of the segment laser beams SLSR through a space between the first beam cutter 1100′ and the second beam cutter 1200′. For example, an edge portion of each of the segment laser beams SLSR in the long-axis direction LA may be blocked, and an approximately central portion in the long-axis direction LA may be transmitted.

Accordingly, as illustrated in FIG. 23, the energy profile shape of the final laser beam LSRL being passed through the beam cutter 1000′ according to the first comparative embodiment may include only a flat top area FTA in most areas. The energy profile of the final laser beam LSRL being passed through the beam cutter 1000′ according to the first comparative embodiment may not include an energy enhancement area EHA.

In one or more embodiments, the final laser beam LSRL being passed through the beam cutter 1000 may include the flat top area FTA and the energy enhancement area EHA as described above.

The laser lift-off apparatus 1 performs a laser lift-off process using the final laser beam LSRL including the flat top area FTA and the energy enhancement area EHA. Therefore, the reliability of the laser lift-off process can be improved.

FIG. 24 is an enlarged view of a portion corresponding to an XE area of FIG. 18 in the energy profile of the final laser beam LSRL of the laser lift-off apparatus 1. FIG. 25 is an enlarged view of a portion corresponding to the XE area of FIG. 18 in an energy profile of a final laser beam of a laser lift-off apparatus 1 according to a second comparative embodiment.

Referring to FIGS. 24 and 25 in addition to FIGS. 4, 6 and 18, as illustrated in a first graph G1, the energy enhancement area EHA in the final laser beam LSRL may include the first area (or high energy area) W1, the second area (or slope area) W2, and the third area (or margin area) W3 described above with reference to FIG. 4, and the flat top area FTA may include at least a portion of the low energy area W0.

The laser lift-off apparatus 1 can reduce or minimize a width L1 of the second area W2 by placing the beam cutter 1000 close or closer to the image plane (e.g., the stage STG) as illustrated in FIG. 6.

For example, the second area W2 may be formed by diffraction of the segment laser beams SLSR as the segment laser beams SLSR is passed through the openings of the beam cutter 1000. The second area W2 may be an area where the energy density of the final laser beam LSRL continuously changes due to diffraction of the segment laser beams SLSR between the first area W1 and the third area W3 (e.g., a boundary between the first opening OP1 and the second opening OP2 or a boundary between the third opening OP3 and the fourth opening OP4). Because a distance over which the laser beam LSR is diffracted decreases as the beam cutter 1000 is placed closer to the image plane, the width L1 of the second area W2 can be reduced or minimized. The width L1 of the second area W2 may be about 12 mm or less.

In one or more embodiments, in the laser lift-off apparatus 1 according to the second comparative embodiment, a beam cutter 1000 may be placed before a long-axis Fourier lens 800 on the path of a laser beam LSR. In this case, as illustrated in a second graph G2 of FIG. 25, a width L2 of a second area W2 may increase, and the range of a portion having energy between a first energy E1 and a second energy E2 may increase.

In the laser lift-off apparatus 1, because the width L1 of the second area W2 is minimized or reduced as described above, it is possible to reduce or prevent the likelihood of the active area AA being irradiated with a laser beam LSR having the first energy E1 from being irradiated with a laser beam LSR having higher energy than the first energy E1 and thus being damaged. In one or more embodiments, it is possible to reduce or prevent the likelihood of the protruding area A being irradiated with a laser beam LSR having the second energy E2 from being irradiated with a laser beam LSR having lower energy than the second energy E2 and thus being less lifted off.

The laser lift-off apparatus 1 can adjust the positions and widths of the flat top area FTA and the energy enhancement area EHA by adjusting the position of the beam cutter 1000 in the long-axis direction LA as described above. Therefore, it may be suitable to secure the minimum width of the third area W3.

For example, the energy enhancement area EHA can be moved toward an edge by adjusting the position of the beam cutter 1000 in the long-axis direction LA. Accordingly, a boundary point between the third area W3 and the second area W2 may be located closer to the edge than to a boundary of the active area AA. Therefore, the width of the third area W3 can be secured, and damage to the active area AA can be minimized or reduced. The width of the third area W3 may be about 4 mm or more.

Hereinafter, other embodiments of the laser lift-off apparatus according to one or more embodiments and a substrate lift-off method using the laser lift-off apparatus will be described in more detail. In the following embodiments, the same elements as those of the above-described embodiments will be indicated by the same reference numerals, and their redundant descriptions may not be provided or may be given briefly, and differences will be mainly described.

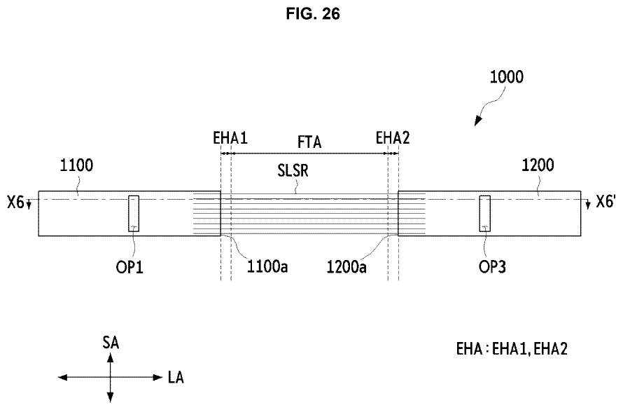

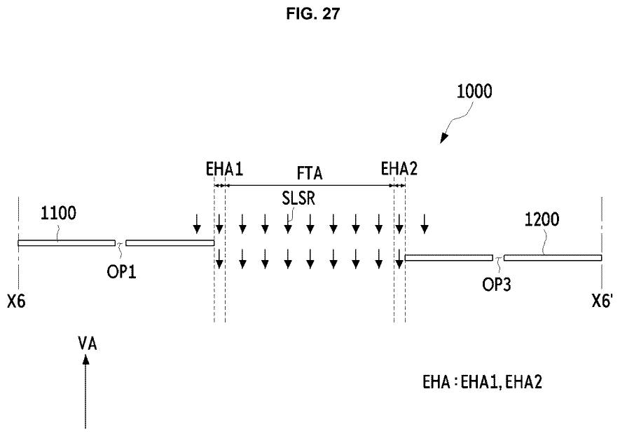

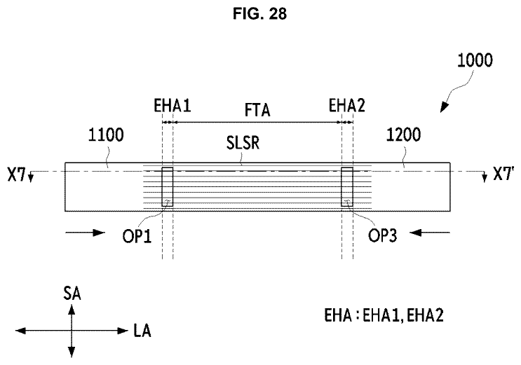

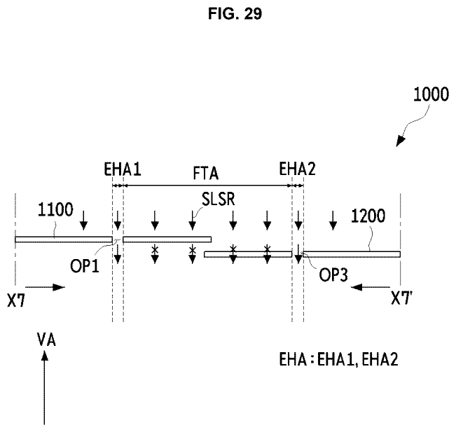

FIG. 26 is a plan view illustrating a first laser irradiation operation using a beam cutter 1000 according to one or more embodiments. FIG. 27 is a cross-sectional view illustrating the first laser irradiation operation using the beam cutter 1000 according to one or more embodiments. FIG. 28 is a plan view illustrating a second laser irradiation operation using the beam cutter 1000 according to one or more embodiments. FIG. 29 is a cross-sectional view illustrating the second laser irradiation operation using the beam cutter 1000 according to one or more embodiments.

Referring to FIGS. 26 through 29, a laser lift-off apparatus 1 is different from the laser lift-off apparatus 1 described with reference to FIG. 7, and/or the like, with respect to differences in the shape of the beam cutter 1000 and the process of the substrate lift-off method.

For example, the beam cutter 1000 of the laser lift-off apparatus 1 may include a first beam cutter 1100 and a second beam cutter 1200. The first beam cutter 1100 may include a first opening OP1, and the second beam cutter 1200 may include a third opening OP3. Unlike in the laser lift-off apparatus 1 described with reference to FIG. 7, and/or the link, in the laser lift-off apparatus 1, the first beam cutter 1100 may not include a second opening OP2, and the second beam cutter 1200 may not include a fourth opening OP4.

The substrate lift-off method using the laser lift-off apparatus 1 may include the first laser irradiation operation and the second laser irradiation operation.

First, in the first laser irradiation operation, as illustrated in FIGS. 26 and 27, an end 1100a of the first beam cutter 1100 may coincide with an outer boundary (e.g., a left boundary in the drawings) of a first energy enhancement area EHA1, and an end 1200a of the second beam cutter 1200 may coincide with an outer boundary (e.g., a right boundary in the drawings) of a second energy enhancement area EHA2. That is, a space may be formed between the first beam cutter 1100 and the second beam cutter 1200. The space may be formed as a combined area of the first energy enhancement area EHA1, a flat top area FTA, and the second energy enhancement area EHA2.

In the first laser irradiation operation, the beam cutter 1000 may be configured to transmit a portion of each of segment laser beams SLSR through the space between the first beam cutter 1100 and the second beam cutter 1200. For example, an edge portion of each of the segment laser beams SLSR in the long-axis direction LA may be blocked, and an approximately central portion may be transmitted.

Accordingly, in the first laser irradiation operation, a final laser beam LSRL may have the same energy density intensity in the flat top area FTA and the energy enhancement area EHA. Therefore, in a display device DD (see FIG. 1) irradiated with the final laser beam LSRL of the flat top area FTA and the energy enhancement area EHA, the same level of energy may be applied to an active area AA, a middle area B, a protruding area A, and a boundary area BR.

Next, in the second laser irradiation operation, as illustrated in FIG. 28 and FIG. 29, each of the first beam cutter 1100 and the second beam cutter 1200 may move toward the center in the long-axis direction LA. At this time, the first opening OP1 of the first beam cutter 1100 may be placed to coincide with the first energy enhancement area EHA1, and the third opening OP3 of the second beam cutter 1200 may be placed to coincide with the second energy enhancement area EHA2. A width of the first opening OP1 of the first beam cutter 1100 in the long-axis direction LA may be equal to a width of the first energy enhancement area EHA1 in the long-axis direction LA, and a width of the third opening OP3 of the second beam cutter 1200 in the long-axis direction LA may be equal to a width of the second energy enhancement area EHA2 in the long-axis direction LA.

In the second laser irradiation operation, the beam cutter 1000 may be configured to transmit a portion of each of the segment laser beams SLSR through the first opening OP1 of the first beam cutter 1100 and the third opening OP3 of the second beam cutter 1200. For example, of each of the segment laser beams SLSR, a portion overlapping the first opening OP1 and the third opening OP3 (i.e., overlapping the energy enhancement area EHA) may be transmitted, and the other portion overlapping the flat top area FTA may be blocked.

Accordingly, in the second laser irradiation operation, additional energy may be applied to the middle area B, the protruding area A, and the boundary area BR in the display device DD (see FIG. 1) being irradiated with the final laser beam LSR of the energy enhancement area EHA.

In the laser lift-off apparatus 1 and the substrate lift-off method using the same, the energy enhancement area EHA may have higher energy than the flat top area FTA in an energy profile of a laser beam LSR irradiated to the display device DD through the first laser irradiation operation and the second laser irradiation operation, as in the energy profile (see FIG. 18) of the final laser beam LSRL of the laser lift-off apparatus 1 described above with reference to FIG. 7, and or the like.

In concluding the detailed description, those skilled in the art will appreciate that many variations and modifications can be made to the disclosed embodiments without substantially departing from the principles of the present disclosure. Therefore, the disclosed embodiments of the present disclosure are used in a generic and descriptive sense only and not for purposes of limitation.

What is claimed is:

1. A laser lift-off apparatus configured to convert a first beam into a second beam having a width in a first direction and in a second direction different from the first direction, the laser lift-off apparatus comprising:
a laser beam generator configured to generate the first beam;
a homogenizer configured to homogenize the first beam; and
a beam cutter comprising a first beam cutter and a second beam cutter defining at least two openings having different respective lengths in the first direction, and configured to generate the second beam by transmitting and blocking respective portions of the first beam.

2. The laser lift-off apparatus of claim 1, wherein the first beam cutter defines a first opening, and a second opening extending from the first opening in the second direction, and
wherein the second beam cutter defines a third opening, and a fourth opening extending from the third opening in the second direction.

3. The laser lift-off apparatus of claim 2, wherein a width of the first opening in the first direction is greater than a width of the second opening in the first direction, and
wherein a width of the third opening in the first direction is greater than a width of the fourth opening in the first direction.

4. The laser lift-off apparatus of claim 2, wherein the first beam cutter comprises a first end,
wherein the second beam cutter comprises a second end facing the first end,
wherein the second opening bifurcates the first end, and
wherein the third opening bifurcates the second end.

5. The laser lift-off apparatus of claim 2, wherein an energy profile of the second beam comprises a first area, and a second area having higher energy than the first area.

6. The laser lift-off apparatus of claim 5, wherein the first area corresponds to the first beam passing through the second opening and the fourth opening.

7. The laser lift-off apparatus of claim 6, wherein the second area comprises a first sub-area, and a second sub-area opposite to the first sub-area with the first area therebetween,
wherein the first sub-area corresponds to the first beam passing through the first opening, and
wherein the second sub-area corresponds to the first beam passing through the third opening.

8. The laser lift-off apparatus of claim 5, wherein the second area comprises:
a margin area on a side of the first area;
a slope area on a side of the margin area; and
a high energy area on a side of the slope area.

9. The laser lift-off apparatus of claim 8, wherein a width of the margin area is about 4 mm or more, and
wherein a width of the slope area is about 12 mm or less.

10. The laser lift-off apparatus of claim 2, wherein a shape of the first beam cutter and a shape of the second beam cutter are symmetrical with respect to an axis extending in the first direction.

11. The laser lift-off apparatus of claim 1, wherein the first beam cutter and the second beam cutter are arranged alternately in a third direction that is different from the first direction and the second direction.

12. The laser lift-off apparatus of claim 11, wherein the first beam cutter and the second beam cutter further comprise a driver configured to provide a driving force in at least one of the first direction or the second direction.

13. The laser lift-off apparatus of claim 1, further comprising a telescope lens between the laser beam generator and the homogenizer, and configured to magnify the first beam, or configured to transmit the first beam at a same magnification.

14. The laser lift-off apparatus of claim 13, further comprising a short-axis slit between the homogenizer and the beam cutter, and defining an opening having a short width in the first direction and a long width in the second direction.

15. The laser lift-off apparatus of claim 14, further comprising a short-axis Fourier lens between the homogenizer and the short-axis slit, and configured to focus the first beam transmitted through the telescope lens onto the short-axis slit along the first direction.

16. The laser lift-off apparatus of claim 14, further comprising a long-axis Fourier lens between the short-axis slit and the beam cutter, and configured to focus the first beam transmitted through the telescope lens onto an image plane to which the second beam is incident.

17. The laser lift-off apparatus of claim 14, further comprising a projection lens between the short-axis slit and the beam cutter, and configured to adjust a width of the first beam passing through the short-axis slit in at least any one of the first direction or the second direction.

18. A laser lift-off apparatus configured to convert a first beam into a second beam having a width in a first direction and in a second direction that is different from the first direction, the laser lift-off apparatus comprising:
a laser beam generator configured to generate the first beam;
a homogenizer configured to homogenize the first beam; and
a beam cutter comprising a first beam cutter defining a first opening extending in the second direction and a second beam cutter defining a second opening extending in the second direction, and configured to generate the second beam by transmitting and blocking respective portions of the first beam.

19. The laser lift-off apparatus of claim 18, wherein an energy profile of the second beam comprises a first area corresponding to the first beam passing through a space between the first beam cutter and the second beam cutter in the second direction, and a second area having higher energy than the first area.

20. The laser lift-off apparatus of claim 19, wherein the second area comprises:
a first sub-area corresponding to the first beam passing through the first opening and the first beam passing through the space; and
a second sub-area opposite to the first sub-area with the first area therebetween, and corresponding to the first beam passing through the second opening and the first beam passing through the space.

21. A substrate lift-off method for lifting off a carrier substrate from a first substrate of a display device comprising the carrier substrate, the first substrate above the carrier substrate, a barrier layer above the first substrate and that is larger than the first substrate in a plan view, and a second substrate above the barrier layer, the display device having a first area in which pixels are arranged, and a second area outside the first area and in which the barrier layer does not overlap the first substrate, the substrate lift-off method comprising:
irradiating a second beam, which is generated from a laser lift-off apparatus comprising a laser beam generator configured to generate a first beam, a homogenizer configured to homogenize the first beam, and a first beam cutter and a second beam cutter for generating the second beam by transmitting and blocking respective portions of the first beam, to the first area and to the second area by separating the first beam cutter and the second beam cutter; and
irradiating the second beam to the second area by moving the first beam cutter and the second beam cutter closer to each other, an energy intensity of the second beam irradiated to the first area being less than an energy intensity of the second beam irradiated to the second area.

22. The substrate lift-off method of claim 21, wherein the first beam cutter defines a first opening, and wherein the second beam cutter defines a second opening, the method further comprising:
passing the first beam through a space between the first beam cutter and the second beam cutter when irradiating the second beam to the first area and the second area by separating the first beam cutter and the second beam cutter, and
passing the first beam through a space between the first opening and the second opening when irradiating the second beam to the second area by moving the first beam cutter and the second beam cutter closer to each other.

23. The substrate lift-off method of claim 21, wherein the display device further has a third area between the first area and the second area, and
wherein an energy intensity of the second beam irradiated to the third area is greater than or equal to the energy intensity of the second beam irradiated to the first area, and less than or equal to the energy intensity of the second beam irradiated to the second area.
